(19) United States
(12) Patent Application Publication
(10) Pub. No.: US 2025/0344548 A1
(43) Pub. Date: Nov. 6, 2025

(54) SEMICONDUCTOR LIGHT-RECEIVING ELEMENT

(71) Applicant: HAMAMATSU PHOTONICS K.K., Hamamatsu-shi, Shizuoka (JP)

(72) Inventors: Keiki TAGUCHI, Hamamatsu-shi, Shizuoka (JP); Hajime ISHIHARA, Hamamatsu-shi, Shizuoka (JP); Yoshiaki OHSHIGE, Hamamatsu-shi, Shizuoka (JP); Kenji MAKINO, Hamamatsu-shi, Shizuoka (JP)

(73) Assignee: HAMAMATSU PHOTONICS K.K., Hamamatsu-shi, Shizuoka (JP)

(21) Appl. No.: 18/868,883

(22) PCT Filed: Feb. 15, 2023
(86) PCT No.: PCT/JP2023/005277

§ 371 Date: Nov. 25, 2024

(30) Foreign Application Priority Data
Jun. 3, 2022 (JP) 2022-091033

(51) Int. Cl. H10F 77/124; H10F 30/22; H10F 77/14

(52) U.S. Cl. CPC H10F 77/1248; H10F 77/1243; H10F 77/146; H10F 30/22

(57) ABSTRACT

Provided is a semiconductor light-receiving element including: a substrate; a semiconductor lamination portion formed on a first region of the substrate; and a first electrode and a second electrode which are electrically connected to the semiconductor lamination portion. The semiconductor lamination portion includes a light absorbing layer that has a first conductivity type and contains InₓGa₁₋ₓAs, a buffer layer that has the first conductivity type and is provided between the substrate and the light absorbing layer, and a second region that has a second conductivity type different from the first conductivity type, is located on a side opposite to the substrate with respect to the light absorbing layer, and is in contact with the light absorbing layer.

### TECHNICAL FIELD

The present disclosure relates to a semiconductor light-receiving element.

### BACKGROUND ART

Patent Literature 1 discloses a photodiode. The photodiode includes an inclined surface reflection portion formed in an InP substrate, a light-receiving portion including a p electrode, a diffraction grating, and an InGaAs light absorbing layer, and an n electrode. Light incident from a surface in a vertical direction is totally reflected by the inclined surface reflection portion, an optical path thereof is converted to an obliquely upward direction, and the light is incident to the light absorbing layer in the light-receiving portion in an obliquely downward direction. After propagating through the light absorbing layer, the obliquely incident light is reflected in a direction opposite to the incident direction by the diffracting grating and the p electrode provided on an upper part of the light-receiving portion, and is absorbed again by the light absorbing layer.

### CITATION LIST

### Patent Literature

Patent Literature 1: Japanese Unexamined Patent Publication No. 2009-117499

### SUMMARY OF INVENTION

### Technical Problem

By the way, in the above-described technical field, there is a demand for a further increase in an operating speed. To achieve this, it is conceivable to shorten an electron migration distance by thinning the light absorbing layer. However, when the light absorbing layer is made thin, a decrease in sensitivity occurs. With regard to this, in the photodiode described in Patent Literature 1, the effective thickness of the absorption layer is increased by propagating light along an optical path in a direction oblique to the light absorbing layer. According to this, it is considered that the decrease in sensitivity due to reduction in thickness of the light absorbing layer is suppressed, and thus an increase in speed is achieved.

However, in the photodiode described in Patent Literature 1, since the optical path that is oblique to the light absorbing layer is formed, there is a concern that processing of forming the inclined surface reflection portion in the substrate, and the like are necessary, and thus the cost may increase.

An object of the present disclosure is to provide a semiconductor light-receiving element capable of achieving an increase in speed while suppressing an increase in cost.

### Solution to Problem

A semiconductor light-receiving element according to the present disclosure is [1] “A semiconductor light-receiving element that receives incident in at least one wavelength band among a band of 1.3 μm, a band of 1.55 μm, and a band of 1.6 μm, and generates an electrical signal in correspondence with the incident light, including: a substrate; a semiconductor lamination portion formed on a first region of the substrate; and a first electrode and a second electrode which are electrically connected to the semiconductor lamination portion, in which the semiconductor lamination portion includes a light absorbing layer that has a first conductivity type and contains InₓGa₁₋ₓAs, a buffer layer that has the first conductivity type and is provided between the substrate and the light absorbing layer, and a second region that has a second conductivity type different from the first conductivity type, is located on a side opposite to the substrate with respect to the light absorbing layer, and is in contact with the light absorbing layer, the first electrode is connected to a first portion that has the first conductivity type and is located on the substrate side with respect to the light absorbing layer in the semiconductor lamination portion, the second electrode is connected to a second portion that has the second conductivity type and is located on a side opposite to the substrate with respect to the light absorbing layer in the semiconductor lamination portion, the In composition x in the light absorbing layer is 0.55 or more, the thickness of the light absorbing layer is 0.6 μm or more and 1.8 μm or less, and the semiconductor light-receiving element is of a rear-surface incident type in which light is incident toward the semiconductor lamination portion from the substrate side, or of a front-surface incident type in which light is incident toward the semiconductor lamination portion from a side opposite to the substrate”.

The semiconductor light-receiving element in [1] targets light in wavelength bands for optical communication such as a band of 1.3 μm (Original-band (O-band)), a band of 1.55 μm (conventional-band (C-band)), and a band of 1.6 μm (long-wavelength-band (L-band)). In the semiconductor light-receiving element, the light absorbing layer provided on the substrate contains InₓGa₁₋ₓAs. In addition, the In composition x in the light absorbing layer is 0.55 or more (and less than 1). As in this case, when the In composition x of InₓGa₁₋ₓAs in the light absorbing layer is set to 0.55 or more, for example, as compared with a case where the In composition x is 0.53, an absorption coefficient is improved (for example, when the composition x is set to 0.62 in the band of 1.55 μm, the absorption coefficient is improved approximately two times). Accordingly, even when the thickness of the light absorbing layer is reduced to approximately 0.6 μm or more and 1.8 μm or less, a decrease in sensitivity can be avoided. That is, an increase in speed is achieved. In addition, in the semiconductor light-receiving element in [1], it is not necessary to form a separate configuration (for example, the inclined surface reflection portion in the photodiode described in Patent Literature 1, and the like) when realizing an increase in speed. Accordingly, according to the semiconductor light-receiving element in [1], an increase in speed is achieved while suppressing an increase in cost.

The semiconductor light-receiving element according to the present disclosure may be [2] “The semiconductor light-receiving element according to [1], in which the buffer layer includes a strain relief layer that has a lattice constant between a lattice constant of the substrate and a lattice constant of the light absorbing layer”. According to the semiconductor light-receiving element in [2], crystallinity of the semiconductor lamination portion is improved.

The semiconductor light-receiving element according to the present disclosure may be [3] “The semiconductor light-receiving element according to [2], in which the buffer layer includes a plurality of the strain relief layers arranged so that the lattice constant becomes close to the lattice constant of the light absorbing layer in a stepwise manner as going from the substrate toward the light absorbing layer”. In addition, the semiconductor light-receiving element according to the present disclosure may be [4] “The semiconductor light-receiving element according to [2], in which the buffer layer includes the strain relief layer of which the lattice constant is changed continuously to be close to the lattice constant of the light absorbing layer as going toward the light absorbing layer from the substrate”. According to the semiconductor light-receiving element in [3] and [4], the crystallinity of the semiconductor lamination portion is reliably improved.

The semiconductor light-receiving element according to the present disclosure may be [5] “The semiconductor light-receiving element according to any one of [1] to [4], in which the semiconductor lamination portion further includes a cap layer that has the first conductivity type, is provided on the light absorbing layer on a side opposite to the substrate with respect to the light absorbing layer, and contains InAsP, and a contact layer that has the first conductivity type and is provided on the cap layer on a side opposite to the substrate with respect to the light absorbing layer, and contains InGaAs, the second region is formed from the contact layer to the light absorbing layer through the cap layer, and the second portion to which the second electrode is connected is a surface of the second region formed in the contact layer”. According to the semiconductor light-receiving element in [5], contact resistance of the second electrode can be lowered.

The semiconductor light-receiving element according to the present disclosure may be [6] “The semiconductor light-receiving element according to any one of [1] to [5], in which the semiconductor lamination portion further includes a first semiconductor layer that has the first conductivity type and is disposed between the substrate and the light absorbing layer, and a second semiconductor layer that has the first conductivity type, has an impurity concentration lower than an impurity concentration of the first semiconductor layer, and is disposed between the first semiconductor layer and the light absorbing layer”. According to the semiconductor light-receiving element in [6], a further increase in speed can be achieved due to a reduction in the capacitance.

The semiconductor light-receiving element according to the present disclosure may be [7] “The semiconductor light-receiving element according to [6], in which the second semiconductor layer has an impurity concentration higher than an impurity concentration of the light absorbing layer, has a band gap larger than a band gap of the light absorbing layer, and is disposed between the light absorbing layer and the buffer layer”. According to the semiconductor light-receiving element in [7], since the second semiconductor layer has a band gap larger than that of the light absorbing layer, absorption of light in the second semiconductor layer and occurrence of carriers in the second semiconductor layer due to absorption of the light are suppressed, and thus a deterioration in characteristics relating to responsiveness is suppressed. In addition, since the second semiconductor layer has a band gap larger than that of the light absorbing layer, and the second semiconductor layer has an impurity concentration higher than that of the light absorbing layer, a barrier in the second semiconductor layer is reduced.

The semiconductor light-receiving element according to the present disclosure may be [8] “The semiconductor light-receiving element according to [7], in which the thickness of the second semiconductor layer is 0.1 μm or more and 3.0 μm or less, and the impurity concentration of the second semiconductor layer is 2.0×10¹⁴ cm⁻³ or more and 3.0×10¹⁶ cm⁻³ or less”. According to the semiconductor light-receiving element in [8], when the upper limit of the impurity concentration of the second semiconductor layer is set as described above, the second semiconductor layer can be suitably depleted when a bias is applied. In addition, when the thickness of the second semiconductor layer is set within the above-described range, it is possible to suppress a decrease in response speed and an increase in series resistance of the semiconductor light-receiving element.

The semiconductor light-receiving element according to the present disclosure may be [9] “semiconductor light-receiving element according to [5], in which the semiconductor lamination portion further includes a third semiconductor layer that is provided between the light absorbing layer and the cap layer, and has a band gap between the band gap of the light absorbing layer and the band gap of the cap layer”. According to the semiconductor light-receiving element in [9], the difficulty in extracting carriers due to a sudden change in the band gap between the cap layer and the light absorbing layer is suppressed.

The semiconductor light-receiving element according to the present disclosure may be “The semiconductor light-receiving element according to any one of [1] to [9], in which at least one layer of the buffer layer is semi-insulated by being doped with Fe”. According to the semiconductor light-receiving element in [10], crystallinity is improved.

The semiconductor light-receiving element according to the present disclosure may be “The semiconductor light-receiving element according to any one of [1] to [10], where the In composition x in the light absorbing layer is 0.57 or more, and the thickness of the light absorbing layer is 1.2 μm or less”. In addition, the semiconductor light-receiving element according to the present disclosure may be “The semiconductor light-receiving element according to any one of [1] to [11], in which the In composition x in the light absorbing layer is 0.59 or more, and the thickness of the light absorbing layer is 0.7 μm or less”. According to the semiconductor light-receiving element in and [12], an increase in speed is achieved due to a further reduction in thickness of the light absorbing layer.

The semiconductor light-receiving element according to the present disclosure may be “The semiconductor light-receiving element according to any one of [1] to [12], in which the substrate contains a semi-insulating semiconductor”. According to the semiconductor light-receiving element in [13], a reduction in capacitance can be achieved.

The semiconductor light-receiving element according to the present disclosure may be “The semiconductor light-receiving element according to any one of [1] to [13], in which the substrate contains an insulating substance or a semi-insulating semiconductor, and the semiconductor lamination portion is bonded to the substrate”. According to the semiconductor light-receiving element in [14], since the substrate and the semiconductor lamination portion are configured separately and are directly bonded to each other to construct the semiconductor light-receiving element, it possible to increase the diameter and it is possible to reduce the cost by fabricating optical components with inexpensive materials.

### Advantageous Effects of Invention

According to the present disclosure, it is possible to provide a semiconductor light-receiving element capable of achieving an increase in speed while suppressing an increase in cost.

### BRIEF DESCRIPTION OF DRAWINGS

FIG. 1 is a schematic side view illustrating a laser device according to an embodiment.

FIG. 2 is a plan view of a semiconductor light-receiving element illustrated in FIG. 1.

FIG. 3 is a cross-sectional view taken along line III-III in FIG. 2.

FIG. 4 is a cross-sectional view taken along line IV-IV in FIG. 2.

FIG. 5 is a cross-sectional view taken along line V-V in FIG. 2.

FIG. 6 is a graph illustrating a relationship between a composition and an absorption coefficient of a light absorbing layer.

FIG. 7 is a schematic side view illustrating a configuration of an optical device according to a modification example.

### DESCRIPTION OF EMBODIMENTS

Hereinafter, an embodiment will be described in detail with reference to the accompanying drawings. Note that, in the drawings, the same reference numeral will be given to the same or equivalent element, and redundant description thereof may be omitted.

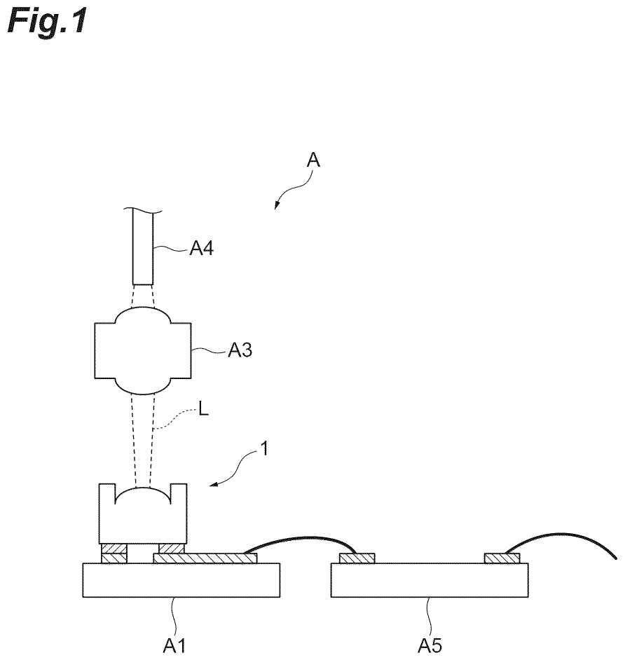

FIG. 1 is a schematic side view illustrating an optical device according to an embodiment. As illustrated in FIG. 1, an optical device A includes a semiconductor light-receiving element 1. The optical device A targets light in wavelength bands for optical communication such as a band of 1.3 μm (Original-band (O-band)), a band of 1.55 μm (conventional-band (C-band)), and a band of 1.6 μm (long-wavelength-band (L-band)), converts the light into an electrical signal, and outputs the electrical signal. The band of 1.3 μm is, for example, a wavelength range of from 1.26 μm to 1.36 μm. The band of 1.55 μm is, for example, a wavelength range of from 1.53 μm to 1.565 μm. The band of 1.6 μm is, for example, a wavelength range of greater than 1.565 μm and 1.625 μm or less. In addition, the light in a wavelength band for communication is light having a peak within a wavelength range of any of the wavelength bands (that is, a wavelength other than the peak may be out of the wavelength range of the wavelength band).

Accordingly, the semiconductor light-receiving element 1 also targets the wavelength bands, receives incident light L having a wavelength pertaining to at least one wavelength band among the wavelength bands, and generates an electrical signal in correspondence with the incident light. The semiconductor light-receiving element 1 is mounted on a submount A1. The light L is guided by an optical fiber A4, and is condensed toward a light-receiving portion of the semiconductor light-receiving element 1 by a lens A3.

An electrical signal generated by the semiconductor light-receiving element 1 is input to a transimpedance amplifier (TIA) A5 via electrode pads (schematically by hatching in FIG. 1 and the like) and wires provided on the submount A1, and is converted into a voltage by the transimpedance amplifier A5 before being output to the outside. Note that, here, the semiconductor light-receiving element 1 is mounted on the submount A1 with a rear surface 10b of the following substrate 10 facing the lens A3 and optical fiber A4. Note that, here, the semiconductor light-receiving element 1 is of a rear-surface incident type in which light is incident toward the following semiconductor lamination portion 20 from the substrate 10 side. More specifically, in this example, the semiconductor light-receiving element 1 receives light incident from the following rear surface 10b, and the light is guided from the substrate 10 side to the semiconductor lamination portion 20.

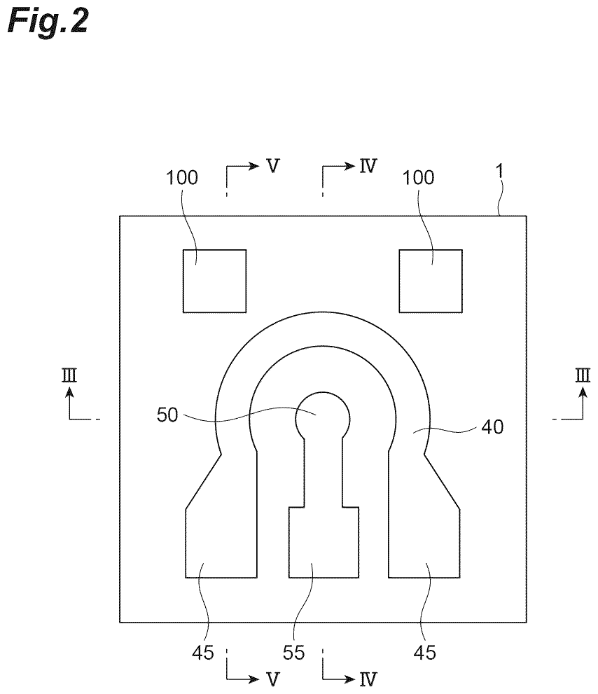

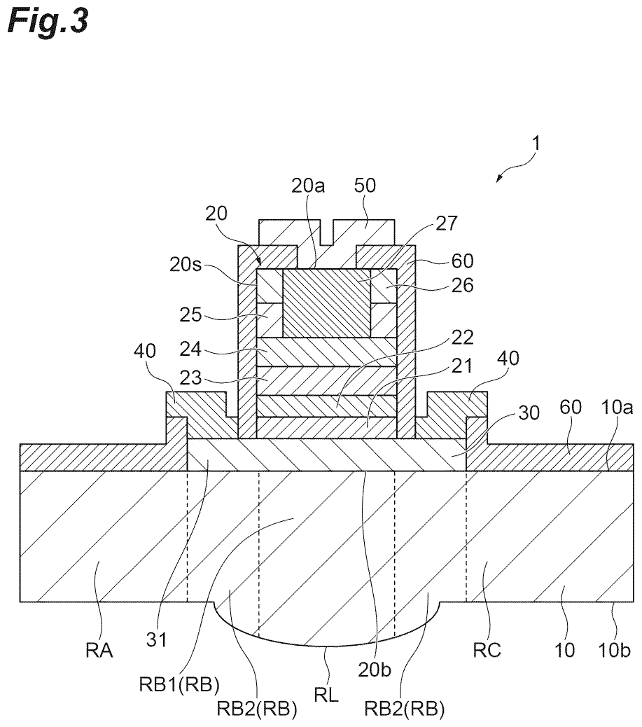

FIG. 2 is a plan view of the semiconductor light-receiving element shown in FIG. 1. FIG. 3 is a cross-sectional view taken along line III-III in FIG. 2. As illustrated in FIGS. 2 and 3, the semiconductor light-receiving element 1 includes the substrate 10, the semiconductor lamination portion 20, a first electrode 40 (here, a cathode), and a second electrode 50 (here, an anode).

The substrate 10 contains a semi-insulating semiconductor. Here, the substrate 10 is a semi-insulating semiconductor substrate consisting of, for example, InP. The substrate 10 includes a front surface 10a and the rear surface 10b on a side opposite to the front surface 10a. In addition, the substrate 10 includes a plurality of regions RA, RB (first region), and RC arranged sequentially along the front surface 10a and the rear surface 10b. The region RB is a region between the region RA and the region RC, and the semiconductor lamination portion 20 is provided in the region RB. More specifically, the region RB includes a central side region RB1, and regions RB2 located on both sides (the regions RA and RC sides) of the region RB1. Here, the rear surface 10b of the substrate 10 is an incident surface of the light L, and a lens RL that condenses the light L is formed in the rear surface 10b. The lens RL is formed to partially overlap the region RB2 with the region RB1 set as a center.

As described above, the semiconductor lamination portion 20 is formed on the region RB of the substrate 10, and is a semiconductor mesa protruding from the front surface 10a. The semiconductor lamination portion 20 includes a rear surface 20b on the substrate 10 side and a front surface 20a on a side opposite to the substrate 10. As described above, in this example, light is incident to the semiconductor lamination portion 20 from the rear surface 20b side. The semiconductor lamination portion 20 includes a buffer layer 30 that has a first conductivity type (here, an N type, and as an example, an N⁺ type). The buffer layer 30 is provided so as to overlap the region RB2 with the region RB1 set as a center. Here, the semiconductor lamination portion 20 is in contact with the front surface 10a of the substrate 10 at the buffer layer 30.

Layers of the semiconductor lamination portion 20 other than the buffer layer 30 are provided in a portion that overlaps the region RB1 in the buffer layer 30 when viewed from a direction intersecting the front surface 10a. The buffer layer 30 includes a first portion 31 exposed from the other layers of the semiconductor lamination portion 20 (and a protective film 60 described below) when viewed from a direction intersecting the front surface 10a, and a junction with the first electrode 40 is formed in the first portion 31. The buffer layer 30 contains, for example, InP. As an example, the buffer layer 30 consists of N⁺—InP.

The semiconductor lamination portion 20 includes buffer layers 21, 22, and 23, a light absorbing layer 24, a cap layer 25, and a contact layer 26 which are sequentially laminated on the buffer layer 30 from the substrate 10 side. The buffer layers 21 and 22 have a first conductivity type (for example, an N⁺ type). The buffer layer 23 has a first conductivity type (for example, an N⁻ type). The buffer layers 21, 22, and 23 contain InAsP. As an example, the buffer layer 21 consists of N⁺—InAs_{0.05}P, the buffer layer 22 consists of N⁺—InAs_{0.10}P, and the buffer layer 23 consists of N⁻—InAs_{0.15}P (or N⁻—InGaAsP).

According to this, the buffer layers 21, 22, and 23 function as strain relief layers having a lattice constant between a lattice constant of the substrate 10 and a lattice constant of the light absorbing layer 24. In other words, the semiconductor lamination portion 20 includes a plurality of strain relief layers (step layers) arranged so that the lattice constant becomes close to the lattice constant of the light absorbing layer 24 in a stepwise manner as going from the substrate 10 toward the light absorbing layer 24.

In addition, the buffer layer 23 is disposed to be closer to the light absorbing layer 24 as compared with the buffer layers 21 and 22, and has an impurity concentration lower than impurity concentrations of the buffer layers 21 and 22. Therefore, the semiconductor lamination portion 20 includes a first semiconductor layer (the buffer layer 21 or 22) disposed between the substrate 10 and the light absorbing layer 24, and a second semiconductor layer (the buffer layer 23) having an impurity concentration lower than the impurity concentration of the first semiconductor layer and disposed between the first semiconductor layer and the light absorbing layer 24.

The light absorbing layer 24 is a first conductivity type (for example, an N⁻ type). The light absorbing layer 24 contains InGaAs. Here, the light absorbing layer 24 consists of N⁻—InₓGa₁₋ₓAs. An In composition x of the light absorbing layer 24 is 0.55 or more (and less than 1). Here, the In composition x is 0.59 as an example. The thickness of the light absorbing layer 24 (thickness along a lamination direction of the semiconductor lamination portion 20) is from 0.6 μm to 1.8 μm, and here, as an example, the thickness is 0.7 μm. Note that, the light absorbing layer 24 may be an absorption layer of a mixed crystal of Al, P, Sb, N, or other materials and InGaAs with a band gap in a range of 0.72 eV or less. The ratio of Al, P, Sb, and N (or other materials) mixed into InGaAs can be set to, for example, 5% or less, or 10% or less.

Here, the buffer layer 23 has an impurity concentration higher than an impurity concentration of the light absorbing layer 24. As an example, the impurity concentration of the buffer layer 23 is approximately 2.0×10¹⁴ cm⁻³ or more and 3.0×10¹⁶ cm⁻³, and the impurity concentration of the light absorbing layer 24 is approximately from 1.0×10¹⁴ cm⁻³ to 1.0×10¹⁶ cm⁻³. In addition, the buffer layer 23 has a band gap larger than the band gap of the light absorbing layer 24. When the band gap of the light absorbing layer 24 is 0.72 eV or less as described above, a range of the band gap of the buffer layer 23 can be set to be larger than 0.72 eV and 1.35 eV or less.

According to this, the semiconductor lamination portion 20 has a capacitance reduction layer (the buffer layer 23, the second semiconductor layer) disposed between the first semiconductor layer and the light absorbing layer 24. The requirements for the capacitance reduction layer include an impurity concentration higher than that of the light absorbing layer 24 and depletion when being applied with a bias as described above. The reason for this is as follows. As described above, since the capacitance reduction layer has a band gap larger than that of the light absorbing layer 24, in a case where the impurity concentration is low, a barrier can be created in a conduction band, movement of carriers may be hindered due to a large barrier, and the carriers may not be extracted appropriately.

In addition, since the capacitance reduction layer needs to be depleted when a bias is applied, an upper limit of the impurity concentration can be set to approximately 3.0×10¹⁶ cm⁻³ as described above. Furthermore, the capacitance reduction layer may have a composition that does not absorb incident light (that is, the band gap may be wider than that of the light absorbing layer 24). The reason for this is as follows. When the capacitance reduction layer absorbs incident light, carriers are generated in the capacitance reduction layer. Since the carriers are extracted as signals from the capacitance reduction layer via the light absorbing layer 24, there is a concern that the carriers become slow carriers and may deteriorate responsiveness characteristics.

In other words, when a relationship between the buffer layer 23 and light absorbing layer 24 is set as described above, it is possible to cause the buffer layer 23 to function as a capacitance reduction layer that can reduce capacitance without reducing the carrier response. Since the capacitance reduction layer is effective as long as the capacitance reduction layer is provided, there is no particular limitation to the thickness of the buffer layer 23 as the capacitance reduction layer, but as an example, the thickness may be set to from 0.1 μm to 3 μm.

Note that, a P⁻ type semiconductor layer may be provided between the light absorbing layer 24 and the following semiconductor region 27 that has a second conductivity type, and it is also possible to use the semiconductor layer as the capacitance reduction layer. However, since an N⁻ type semiconductor layer is easier to be manufactured as compared with a P type semiconductor layer and electrons have a higher mobility as compared with a carrier speed in a Player, it is considered more effective to form the N⁻ type buffer layer 23 (to cause the N⁻ type buffer layer 23 to function) as the capacitance reduction layer directly below the light absorbing layer 24 (between the light absorbing layer 24 and the first semiconductor layer and in contact with the light absorbing layer 24).

In addition, in the semiconductor light-receiving element 1, the light absorbing layer 24 is a single layer. The configuration in which the light absorbing layer 24 is a single layer represents that the light absorbing layer 24 does not have a lamination structure formed by laminating two or more layers having different compositions or characteristics. More specifically, the configuration in which the light absorbing layer 24 is a single layer represents, for example, that the light absorbing layer 24 does not have a superlattice structure formed by repeatedly laminating a plurality of layers having different compositions.

The cap layer 25 has a first conductivity type (for example, an N type). The cap layer 25 contains InAsP. As an example, the cap layer 25 consists of N⁻—InAs_{0.15}P. The contact layer 26 has a first conductivity type (for example, an N⁻ type). The contact layer 26 contains InGaAs. As an example, the contact layer 26 consists of N⁻—InGaAs.

A semiconductor region (a second region) 27 that has a second conductivity type (here, P⁺ type) is formed in the semiconductor lamination portion 20. The semiconductor region 27 can be formed, for example, by impurity diffusion, ion implantation, or the like. The semiconductor region 27 extends from the front surface 20a of the semiconductor lamination portion 20 toward the substrate 10 side. Here, the front surface 20a of the semiconductor lamination portion 20 (the surface facing a side opposite to the substrate 10) is a surface of the contact layer 26. The P⁺ type semiconductor region 27 is formed so as to extend from the contact layer 26 to the light absorbing layer 24 via the cap layer 25.

Here, the semiconductor region 27 is also formed in the light absorbing layer 24. In an example in which the thickness of the light absorbing layer 24 is 0.7 μm, a range of approximately 0.2 μm of the light absorbing layer 24 on the cap layer 25 side is the semiconductor region 27. That is, in this example, an N⁻ region with a thickness of 0.5 μm and a P⁺ region with a thickness of 0.2 μm are included inside the light absorbing layer 24, and a boundary between the regions is formed. As an example, a terminal end of the P⁺ region is a position where a P type impurity concentration is 1×10¹⁷ cm⁻³ or less. However, the boundary between the N⁻ region and the P⁺ region may be formed outside the light absorbing layer 24. That is, a lower limit of the thickness of the semiconductor region 27 in the light absorbing layer 24 is 0. On the other hand, as an example, an upper limit of the thickness of the semiconductor region 27 in the light absorbing layer 24 is approximately 0.5 μm.

Note that, In the above examples, the N⁺ type represents that an N type impurity concentration is approximately 1×10¹⁷ cm⁻³ or more. The N⁻ type represents that the N type impurity concentration is approximately 3.0×10¹⁶ cm⁻³ or less that is relatively lower as compared with the N+ type. Also, the P⁺ type represents that the P type impurity concentration is approximately 1×10¹⁷ cm⁻³ or more.

Here, the semiconductor light-receiving element 1 includes the protective film 60. The protective film 60 is, for example, an insulating film. A part of the front surface 20a (top surface) of the semiconductor lamination portion 20 and a side surface 20s of the semiconductor lamination portion 20 extending from a peripheral edge of the front surface 20a toward the substrate 10 side are covered with the protective film 60. On the other hand, the remaining portion of the front surface 20a of the semiconductor lamination portion 20 (here, the surface of the P type semiconductor region 27) is exposed from the protective film 60. Then, the second electrode 50 is formed on the portion of the front surface 20a exposed from the protective film 60, and a junction between the second electrode 50 and the semiconductor region 27 (contact layer 26) is formed. That is, the second electrode 50 is connected to a second portion (semiconductor region 27) that has the second conductivity type and is located on a side opposite to the substrate 10 with respect to the light absorbing layer 24 in the semiconductor lamination portion 20. On the other hand, the first electrode 40 is connected to the first portion 31 (a portion of the buffer layer 30 which is exposed from the protective film 60) that has the first conductivity type and is located on the substrate 10 side with respect to the light absorbing layer 24 in the semiconductor lamination portion 20.

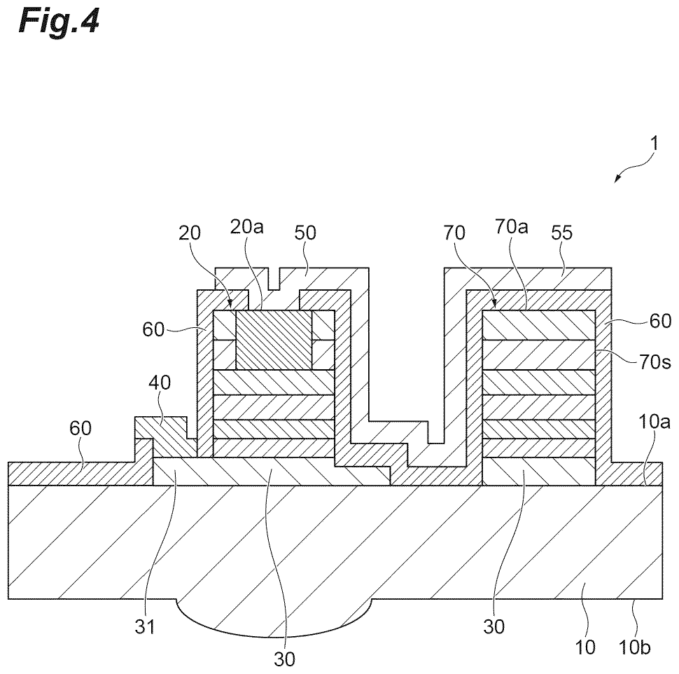

FIG. 4 is a cross-sectional view taken along line IV-IV in FIG. 2. As illustrated in FIGS. 2 and 4, a semiconductor lamination portion 70 is formed on the front surface 10a of the substrate 10 via the buffer layer 30. A structure of the semiconductor lamination portion 70 is similar to the configuration of the semiconductor lamination portion 20 excluding the buffer layer 30 except that the P⁺ type semiconductor region 27 is not formed. The semiconductor lamination portion 70 is entirely covered with the protective film 60.

Here, the second electrode 50 extends from the front surface 20a of the semiconductor lamination portion 20 to a top surface 70a (a surface facing a side opposite to the substrate 10) of the semiconductor lamination portion 70, and forms an anode pad 55 on the top surface 70a. That is, the anode pad 55 is formed on the top surface 70a of the semiconductor lamination portion 70, and is electrically connected to the second electrode 50 via the protective film 60.

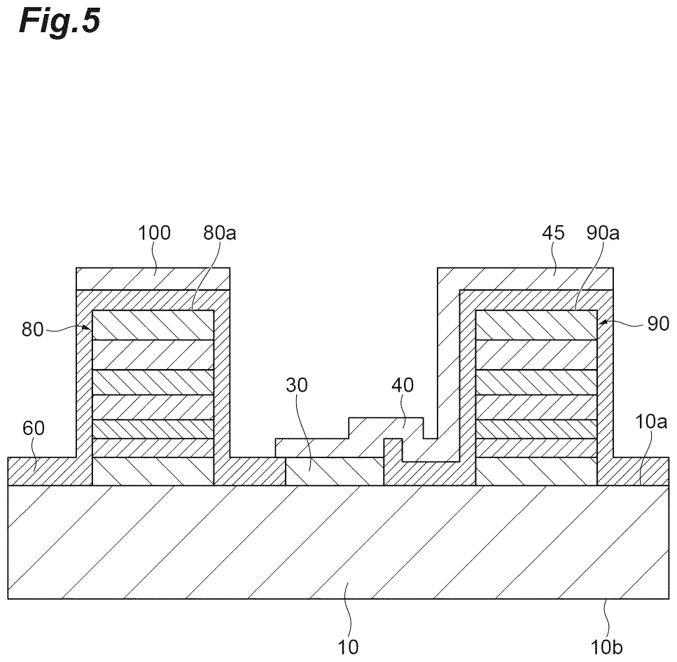

FIG. 5 is a cross-sectional view taken along line V-V in FIG. 2. As illustrated in FIGS. 2 and 5, semiconductor lamination portions 80 and 90 are formed on the front surface 10a of the substrate 10 via the buffer layer 30. A structure of the semiconductor lamination portions 80 and 90 is similar to the structure of the semiconductor lamination portion 20 excluding the buffer layer 30 except that the P type semiconductor region 27 is not formed. The semiconductor lamination portions 80 and 90 are entirely covered with the protective film 60. Here, the first electrode 40 extends from a portion bonded to the buffer layer 30 to a top surface 90a (a surface facing an opposite side to the substrate 10) of the semiconductor lamination portion 90, and forms a cathode pad 45 on the top surface 90a.

That is, the cathode pad 45 electrically connected to the first electrode 40 is formed on the top surface 90a of the semiconductor lamination portion 90 via the protective film 60. On the other hand, a dummy pad 100 is formed on the top surface 80a of the semiconductor lamination portion 80 via the protective film 60. As illustrated in FIG. 2, the cathode pad 45 (and the semiconductor lamination portion 90) is formed as a pair so as to sandwich the anode pad 55 (and the semiconductor lamination portion 70), and a pair of dummy pads 100 (and the semiconductor lamination portion 80) are also formed.

In the optical device A, the semiconductor light-receiving element 1 is disposed and mounted on the submount A1 in such a manner that the front surface 10a of the substrate 10 faces the submount A1 side, that is, the rear surface 10b of the substrate 10 faces a side opposite to the submount A1. According to this, the pair of cathode pads 45, the anode pad 55, and the pair of dummy pads 100 are connected to respective electrode pads provided on the submount A1. As a result, the cathode pads 45 and the anode pad 55 are connected to electrodes electrically connected to the transimpedance amplifier A5 on the submount A1.

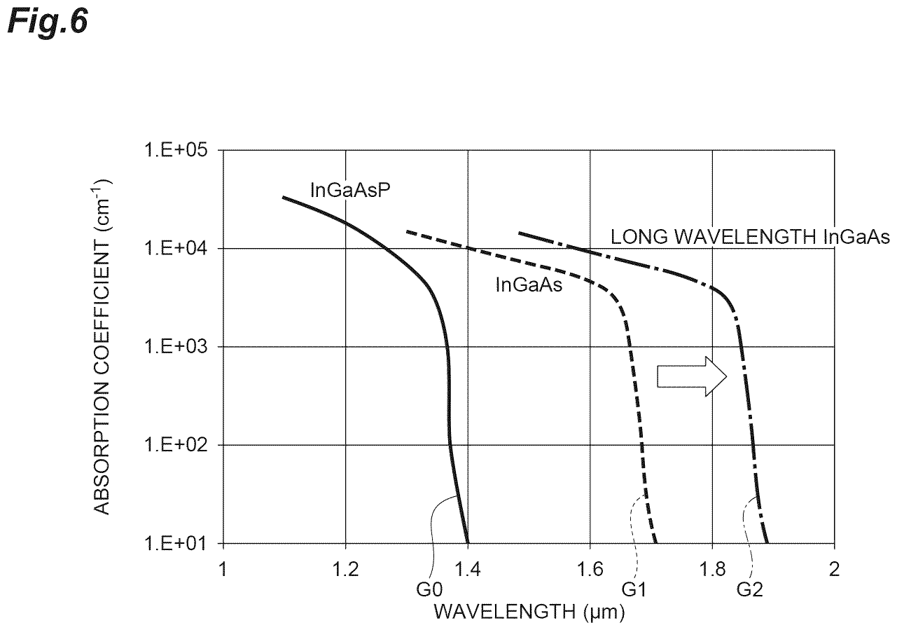

As described above, the semiconductor light-receiving element 1 targets light in wavelength bands for optical communication such as a band of 1.3 μm, a band of 1.55 μm, and a band of 1.6 μm. In the semiconductor light-receiving element 1, the light absorbing layer 24 provided on the semi-insulating semiconductor substrate 10 contains InₓGa₁₋ₓAs. The In composition x of the light absorbing layer 24 is 0.55 or more (and less than 1). In this way, when the In composition x of InₓGa₁₋ₓAs in the light absorbing layer 24 is 0.55 or more (graph G2 in FIG. 6), an absorption coefficient is further improved, for example, as compared with a case in which the In composition x is 0.53 shown in a graph G1 in FIG. 6 (in the example of FIG. 6, the absorption coefficient is improved approximately two times in the band of 1.55 μm). Note that, a graph G0 in FIG. 6 shows a case where the light absorbing layer consisting of InGaAsP is used.

Accordingly, even when the thickness of the light absorbing layer 24 is reduced to approximately from 0.6 μm to 1.8 μm, a decrease in sensitivity can be avoided. That is, an increase in speed is achieved. Furthermore, in the semiconductor light-receiving element 1, it is not necessary to form a separate configuration (for example, the inclined surface reflection portion in the photodiode described in Patent Literature 1, and the like) when realizing an increase in speed. Therefore, according to the semiconductor light-receiving element 1, an increase in speed is achieved while suppressing an increase in cost. However, from the viewpoint of the increase in speed, the semiconductor light-receiving element 1 may be configured so that an optical path oblique to a thickness direction of the light absorbing layer 24 is formed in the light absorbing layer 24.

Note that, as shown in the graphs G1 and G2 of FIG. 6, an absorption edge is shifted to a longer wavelength by increasing the In composition x of the light absorbing layer 24. However, the semiconductor light-receiving element 1 has a characteristic in which the absorption coefficient in the target wavelength band (the band of 1.3 μm, the band of 1.55 μm, and the band of 1.6 μm for optical communication described above) is improved instead of shifting of the absorption edge to a longer wavelength. That is, in the semiconductor light-receiving element 1, a reduction in thickness of the light absorbing layer 24 and a high-speed operation can be realized by improving the absorption coefficient in the target wavelength band. In other words, in the semiconductor light-receiving element 1, a combination of the target wavelength band, and definition of the In composition x and thickness of the light absorbing layer 24 is important. Furthermore, the thinner the light absorbing layer 24 is, the more the effect of the absorption coefficient on the light-receiving sensitivity becomes significant, and thus a configuration for achieving both a restraint response and high light receiving sensitivity as in the semiconductor light-receiving element 1 is effective.

On the other hand, when the In composition x of the light absorbing layer 24 is changed (increased), a deviation between the lattice constant of the light absorbing layer 24 and a lattice constant of the substrate 10 tends to increase, and thus there is a concern that crystallinity will deteriorate when the light absorbing layer 24 is grown on the substrate 10.

Therefore, in the semiconductor light-receiving element 1, the semiconductor lamination portion 20 includes the buffer layers 21 to 23 functioning as strain relief layers having a lattice constant between the lattice constant of the substrate 10 and the lattice constant of the light absorbing layer 24. According to this, the crystallinity of the semiconductor lamination portion 20 including the light absorbing layer 24 is improved. In particular, in the semiconductor light-receiving element 1, the buffer layers 21 to 23 function as a plurality of strain relief layers arranged in such a manner that the lattice constant becomes close to the lattice constant of the light absorbing layer 24 in a stepwise manner from the substrate 10 toward the light absorbing layer 24. As a result, the crystallinity of the semiconductor lamination portion 20 is reliably improved.

In the semiconductor light-receiving element 1, the semiconductor lamination portion 20 includes the cap layer 25 that has a first conductivity type and is provided on the light absorbing layer 24 on a side opposite the substrate 10 with respect to the light absorbing layer 24 and contains InAsP, and the contact layer 26 that has a first conductivity type, is provided on the cap layer 25 on a side opposite the substrate 10 with respect to the light absorbing layer 24, and contains InGaAs. The semiconductor region 27 that has a second conductivity type is formed from the contact layer 26 to the light absorbing layer 24 via the cap layer 25. A portion to which the second electrode 50 is connected is the surface of the semiconductor region 27 formed on the contact layer 26. According to this, contact resistance of the second electrode 50 is lowered.

In addition, in the semiconductor light-receiving element 1, the semiconductor lamination portion 20 includes a first semiconductor layer (the buffer layer 21 or the buffer layer 22) that has a first conductivity type and is disposed between the substrate 10 and the light absorbing layer 24, and a second semiconductor layer (the buffer layer 23) that has the first conductivity type, has an impurity concentration lower than an impurity concentration of the first semiconductor layer, and is disposed between the first semiconductor layer and the light absorbing layer 24. According to this, the capacitance is reduced and a further increase in speed is achieved.

In addition, in the semiconductor light-receiving element 1, the substrate 10 includes a semi-insulating semiconductor. When a conductive substrate is used as the substrate 10, the substrate and the semiconductor lamination portion 20 are electrically conductive and have the same potential. In this case, capacitive coupling between the anode and the cathode is also performed through the protective film 60 (insulating film), and a decrease in capacitance is not expected. In contrast, in the semiconductor light-receiving element 1, a growth layer that becomes the semiconductor lamination portion 20 can be electrically separated by etching or the like up to the semi-insulating or insulating substrate 10. As a result, the capacitive coupling can be prevented, and a decrease in capacitance can be achieved. The substrate 10 can be semi-insulated, for example, by doping Fe or the like into InP or GaAs. Since the lattice constant of InP matches that of InGaAs, an InGaAs layer with satisfactory crystallinity can be directly grown on the semi-insulating substrate 10.

In the semiconductor light-receiving element 1, the buffer layer 23 has an impurity concentration higher than an impurity concentration of the light absorbing layer 24, and has a band gap larger than that of the light absorbing layer 24, and is provided between the light absorbing layer 24 and the first semiconductor layer. In this manner, since the buffer layer 23 has a band gap larger than that of the light absorbing layer 24, absorption of light in the buffer layer 23 and generation of carriers in the buffer layer 23 due to the absorption of light are suppressed, and thus deterioration in characteristics related to responsiveness is suppressed. In addition, since the buffer layer 23 has a band gap larger than that of the light absorbing layer 24, and the buffer layer 23 has an impurity concentration higher than that of the light absorbing layer 24, a barrier in the buffer layer 23 is reduced.

Furthermore, in the semiconductor light-receiving element 1, the thickness of the buffer layer 23 is from 0.1 μm to 3.0 μm, and the impurity concentration of the buffer layer 23 is from 2.0×10¹⁴ cm⁻³ to 3.0×10¹⁶ cm⁻³. In this way, when an upper limit of the impurity concentration of the buffer layer 23 is set as described above, the buffer layer 23 can be suitably depleted when a bias is applied. In addition, when the thickness of the buffer layer 23 is set within the above-described range, it is possible to suppress a decrease in response speed and an increase in series resistance when using a plurality of the semiconductor light-receiving elements connected in series.

In the above-described embodiment, one aspect of the present disclosure is described. Therefore, the present disclosure is not limited to the above-described aspect and may be arbitrarily modified. Next, modification examples will be described.

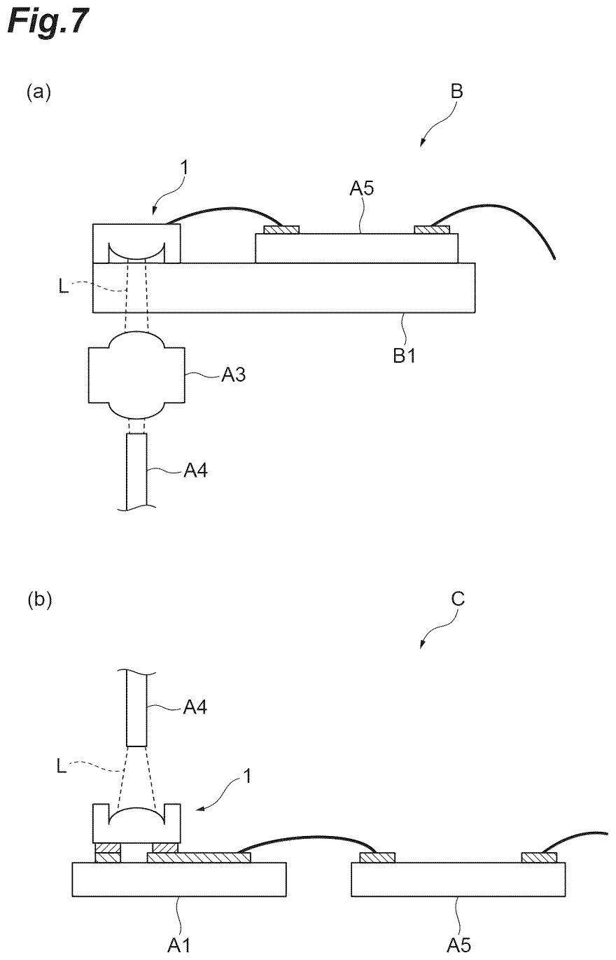

FIG. 7 is a view illustrating a modification example related to a mounting method of a semiconductor light-receiving element. In an optical device B shown in FIG. 7(a), the semiconductor light-receiving element 1 is mounted on a glass substrate B1 so that the rear surface 10b of the substrate 10 faces the glass substrate B1, and is electrically connected directly to the transimpedance amplifier A5 similarly mounted on the glass substrate B1 by a wire. The lens A3 and the optical fiber A4 are arranged on a surface side of the glass substrate B1 which is opposite to a surface on which the semiconductor light-receiving element 1 is mounted, and light L is incident to the semiconductor light-receiving element 1 from the rear surface 10b side through the glass substrate B1. In an optical device C shown in FIG. 7(b), the lens A3 is omitted as compared with the optical device A shown in FIG. 1. Furthermore, the semiconductor light-receiving element 1 may be directly mounted on the transimpedance amplifier A5.

In this way, various aspects are considered for the mounting method of the semiconductor light-receiving element 1 and the optical device including the semiconductor light-receiving element 1. In the above-described examples, the semiconductor light-receiving element 1 is used as a rear-surface incident type. However, the semiconductor light-receiving element 1 may be configured as a front-surface incident type in which light is incident from a side opposite to the substrate 10 toward the semiconductor lamination portion 20. That is, the semiconductor light-receiving element 1 may be configured to receive light incident from the front surface 10a side of the substrate 10. In this case, an opening may be formed so that a light-receiving portion is exposed to the second electrode 50 provided on the light-receiving portion (semiconductor region 27).

Furthermore, in a case where the semiconductor light-receiving element 1 is used as the rear-surface incident type (type in which light is incident from the substrate 10 side toward the semiconductor lamination portion 20), the light may be incident from a side surface of the substrate 10 toward the semiconductor lamination portion 20 by reflection or refraction at the side surface of the substrate 10. In this case, a light incident surface of the substrate 10 may be the front surface 10a or the rear surface 10b. Note that, the side surface of the substrate 10 is a surface that intersects the rear surface 10b and the front surface 10a between the rear surface 10b and the front surface 10a. According to this configuration, it is possible to form an optical path, which is oblique to the thickness direction of the light absorbing layer 24, in the light absorbing layer 24, and further suppression of a decrease in sensitivity, and an increase in the speed can be achieved.

In addition, in the above-described example, the thickness of the light absorbing layer 24 is 0.7 μm, and the In composition x of the light absorbing layer 24 is 0.59 as an example. However, the thickness of the light absorbing layer 24 may be 1.8 μm or less, and the In composition x may be 0.55 or more. In particular, the In composition x of the light absorbing layer 24 may be 0.57 or more, and the thickness of the light absorbing layer may be 1.2 μm or less. Furthermore, the In composition x of the light absorbing layer 24 may be 0.59 or more, and the thickness of the light absorbing layer 24 may be 0.7 μm or less. In these cases, an increase in speed is achieved due to a further reduction in the thickness of the light absorbing layer.

Note that, examples of combinations of each wavelength band and the thickness of the light absorbing layer 24 and the In composition x of the light absorbing layer 24 are listed below. For example, the following (5) can be configured not only for the C-band but also for the O-band and the L-band.

### (1) C-Band.

Sensitivity: 0.86 A/W or more.

Cutoff frequency: 20 GHz or more (for 28 GB or the like).

Thickness of absorption layer: 1.5 μm (details: N⁻ region: 1.3 μm, P⁺ region: 0.2 μm).

In composition x: x=0.55.

### (2) C-Band.

Sensitivity: 0.90 A/W or more.

Cutoff frequency: 20 GHz or more (for high sensitivity product of 28 GB).

Thickness of absorption layer: 1.5 μm (details: N⁻ region: 1.3 μm, P⁺ region: 0.2 μm).

In composition x: x=0.57.

### (3) C-Band.

Sensitivity: 0.80 A/W or more.

Cutoff frequency: 30 GHz or more (for 56 GB or the like).

Thickness of absorption layer: 1.2 μm (details: N⁻ region: 1.0 μm, P⁺ region: 0.2 μm).

In composition x: x=0.57.

### (4) C-Band.

Sensitivity: 0.85 A/W or more.

Cutoff frequency: 30 GHz or more (for high sensitivity product of 56 GB).

Thickness of absorption layer: 1.2 μm (details: N⁻ region: 1.0 μm, P⁺ region: 0.2 μm).

In composition x: x=0.59.

### (5) C-Band.

Sensitivity: 0.7 A/W or more.

Cutoff frequency: 45 GHz or more (for 96 GB or the like).

Thickness of absorption layer: 0.7 μm (details: N⁻ region: 0.5 μm, P⁺ region: 0.2 μm).

In composition x: x=0.59.

### (6) C-Band.

Sensitivity: 0.90 A/W or more.

Cutoff frequency: 16 GHz or more (for 25 GB or the like).

Thickness of absorption layer: 1.8 μm (details: N⁻ region: 1.6 μm, P⁺ region: 0.2 μm).

In composition x: x=0.55.

### (7) C-Band.

Sensitivity: 0.93 A/W or more.

Cutoff frequency: 16 GHz or more (for 25 GB or the like).

Thickness of absorption layer: 1.8 μm (details: N⁻ region: 1.6 μm, P⁺ region: 0.2 μm).

In composition x: x=0.57.

In addition, in the semiconductor light-receiving element 1, the semiconductor lamination portion 20 may include a third semiconductor layer that is provided between the light absorbing layer 24 and the cap layer 25, and has a band gap between the band gap of the light absorbing layer 24 and the band gap of the cap layer 25. The third semiconductor layer has a first conductivity type (for example, N⁻ type) and consists of N⁻—InAsGaP as an example. In this case, the difficulty in extracting carriers due to a sudden change in the band gap between the cap layer 25 and the light absorbing layer 24 is suppressed.

In addition, in the semiconductor light-receiving element 1, at least one layer of the buffer layers 21 to 23, and 30 may be doped with Fe to be semi-insulated and increased in thickness. In this case, crystallinity is improved.

In addition, the buffer layers 21 to 23, and 30 may contain InGaAsP (or may consist of InGaAsP) for the purpose of improving a transmittance in the band of 1.3 μm, the band of 1.55 μm, and the band of 1.6 μm by enlarging the band gap without limitation to InAsP. Furthermore, each layer of the semiconductor lamination portion 20 may contain other elements such as Al.

In addition, in the semiconductor light-receiving element 1, the buffer layers 21 to 23 in which the number of lattices changes in a stepwise manner from the substrate 10 toward the light absorbing layer 24 are used, but a strain relief layer (buffer layer) in which the lattice constant changes continuously from the substrate 10 toward the light absorbing layer 24 to be close to the lattice constant of the light absorbing layer 24 may be used. In the above-described example, the semiconductor light-receiving element 1 includes the cap layer 25 and the contact layer 26 laminated sequentially on the light absorbing layer 24, and the second electrode 50 is connected to the surface of the semiconductor region 27 formed in the contact layer 26. However, in the semiconductor light-receiving element 1, the cap layer 25 may be omitted, and the contact layer 26 may be formed directly on the light absorbing layer 24. Even in this case, the contact resistance of the second electrode 50 is lowered.

Furthermore, from the viewpoint of the increase in speed, the light absorbing layer 24 may be applied to a waveguide type semiconductor light-receiving element. In a waveguide type semiconductor light-receiving element, a ridge waveguide is formed on a semi-insulating InP substrate, and a light-receiving portion including the light absorbing layer 24 is formed in the ridge waveguide. In this way, even in the waveguide type, when employing a light absorbing layer 24 with improved absorptance, it is possible to reduce the capacitance by reducing a length of a light-receiving surface along an extension direction of the waveguide. Also, even though the thickness is the same, the responsiveness is improved by increasing a traveling speed of electrons.

Furthermore, in the semiconductor light-receiving element 1, the substrate 10 may be removed by, for example, etching or polishing, and then the semiconductor lamination portion 20 may be bonded to a substrate consisting of an insulating substance such as quartz or a semi-insulating semiconductor material other than InP (for example, gallium arsenide). In other words, in the semiconductor light-receiving element 1, the substrate 10 may contain an insulating substance or a semi-insulating semiconductor and be configured separately from the semiconductor lamination portion 20, and the semiconductor lamination portion 20 may be bonded (for example, directly) to the substrate 10. In this way, when manufacturing the semiconductor light-receiving element 1 by separately configuring and bonding the substrate 10 and the semiconductor lamination portion 20, it possible to increase the diameter and it is possible to reduce the cost by fabricating optical components with inexpensive materials.

Note that, when bonding the substrate 10 and the semiconductor lamination portion 20 which are configured separately from each other, direct bonding or bonding using a resin can be employed. When a resin is used in bonding between the substrate 10 and the semiconductor lamination portion 20, there is a possibility that light in the target wavelength band may be absorbed depending on properties of the resin, but this is not possible with direct bonding.

Further, the semiconductor light-receiving element according to the present disclosure is a semiconductor light-receiving element configured to receive incident light in at least one of wavelength bands including a band of 1.3 μm, a band of 1.55 μm, and a band of 1.6 μm and to generate an electrical signal in correspondence with the incident light. The semiconductor light-receiving element includes a substrate, a semiconductor lamination portion formed on a first region of the substrate, and a first electrode and a second electrode electrically connected to the semiconductor lamination portion. The semiconductor lamination portion includes a light absorbing layer that has a first conductivity type and contains InₓGa₁₋ₓAs, a buffer layer that has the first conductivity type and is provided between the substrate and the light absorbing layer, and a second region that has a second conductivity type different from the first conductivity type, is located on a side opposite to the substrate with respect to the light absorbing layer, and is in contact with the light absorbing layer. The first electrode is connected to a first portion that has the first conductivity type and is located on the substrate side with respect to the light absorbing layer in the semiconductor lamination portion, the second electrode is connected to a second portion that has the second conductivity type and is located on a side opposite to the substrate with respect to the light absorbing layer in the semiconductor lamination portion, the In composition x in the light absorbing layer may be 0.55 or more, and the thickness of the light absorbing layer may be 1.5 μm or less.

### INDUSTRIAL APPLICABILITY

There is provided a semiconductor light-receiving element capable of achieving an increase in speed while suppressing an increase in cost.

### REFERENCE SIGNS LIST

1: semiconductor light-receiving element, 20: semiconductor lamination portion, 21, 22: buffer layer (strain relief layer, first semiconductor layer), 23: buffer layer (strain relief layer, second semiconductor layer, capacitance reduction layer), 24: light absorbing layer, 25: cap layer, 26: contact layer, 27: semiconductor region (second portion), 31: first portion, 40: first electrode, 50: second electrode.

1. A semiconductor light-receiving element that receives incident light in at least one wavelength band among a band of 1.3 μm, a band of 1.55 μm, and a band of 1.6 μm, and generates an electrical signal in correspondence with the incident light, comprising:
a substrate;
a semiconductor lamination portion formed on a first region of the substrate; and
a first electrode and a second electrode which are electrically connected to the semiconductor lamination portion,
wherein the semiconductor lamination portion includes,
a light absorbing layer that has a first conductivity type and contains InₓGa₁₋ₓAs,
a buffer layer that has the first conductivity type and is provided between the substrate and the light absorbing layer, and
a second region that has a second conductivity type different from the first conductivity type, is located on a side opposite to the substrate with respect to the light absorbing layer, and is in contact with the light absorbing layer,
the first electrode is connected to a first portion that has the first conductivity type and is located on the substrate side with respect to the light absorbing layer in the semiconductor lamination portion,
the second electrode is connected to a second portion that has the second conductivity type and is located on a side opposite to the substrate with respect to the light absorbing layer in the semiconductor lamination portion,
the In composition x in the light absorbing layer is 0.55 or more,
the thickness of the light absorbing layer is 0.6 μm or more and 1.8 μm or less, and
the semiconductor light-receiving element is of a rear-surface incident type in which light is incident toward the semiconductor lamination portion from the substrate side, or of a front-surface incident type in which light is incident toward the semiconductor lamination portion from a side opposite to the substrate.

2. The semiconductor light-receiving element according to claim 1,
wherein the buffer layer includes a strain relief layer that has a lattice constant between a lattice constant of the substrate and a lattice constant of the light absorbing layer.

3. The semiconductor light-receiving element according to claim 2,
wherein the buffer layer includes a plurality of the strain relief layers arranged so that the lattice constant becomes close to the lattice constant of the light absorbing layer in a stepwise manner as going from the substrate toward the light absorbing layer.

4. The semiconductor light-receiving element according to claim 2,
wherein the buffer layer includes the strain relief layer of which the lattice constant is changed continuously to be close to the lattice constant of the light absorbing layer as going toward the light absorbing layer from the substrate.

5. The semiconductor light-receiving element according to claim 1,
wherein the semiconductor lamination portion further includes,
a cap layer that has the first conductivity type, is provided on the light absorbing layer on a side opposite to the substrate with respect to the light absorbing layer, and contains InAsP, and
a contact layer that has the first conductivity type and is provided on the cap layer on a side opposite to the substrate with respect to the light absorbing layer, and contains InGaAs,
the second region is formed from the contact layer to the light absorbing layer through the cap layer, and
the second portion to which the second electrode is connected is a surface of the second region formed in the contact layer.

6. The semiconductor light-receiving element according to claim 1,
wherein the semiconductor lamination portion further includes,
a first semiconductor layer that has the first conductivity type and is disposed between the substrate and the light absorbing layer, and
a second semiconductor layer that has the first conductivity type, has an impurity concentration lower than an impurity concentration of the first semiconductor layer, and is disposed between the first semiconductor layer and the light absorbing layer.

7. The semiconductor light-receiving element according to claim 6,
wherein the second semiconductor layer has an impurity concentration higher than an impurity concentration of the light absorbing layer, has a band gap larger than a band gap of the light absorbing layer, and is disposed between the light absorbing layer and the buffer layer.

8. The semiconductor light-receiving element according to claim 7,
wherein the thickness of the second semiconductor layer is 0.1 μm or more and 3.0 μm or less, and
the impurity concentration of the second semiconductor layer is 2.0×10¹⁴ cm⁻³ or more and 3.0×10¹⁶ cm⁻³ or less.

9. The semiconductor light-receiving element according to claim 5,
wherein the semiconductor lamination portion further includes a third semiconductor layer that is provided between the light absorbing layer and the cap layer, and has a band gap between the band gap of the light absorbing layer and the band gap of the cap layer.

10. The semiconductor light-receiving element according to claim 1,
wherein at least one layer of the buffer layer is semi-insulated by being doped with Fe.

11. The semiconductor light-receiving element according to claim 1,
wherein the In composition x in the light absorbing layer is 0.57 or more, and
the thickness of the light absorbing layer is 1.2 μm or less.

12. The semiconductor light-receiving element according to claim 1,
wherein the In composition x in the light absorbing layer is 0.59 or more, and
the thickness of the light absorbing layer is 0.7 μm or less.

13. The semiconductor light-receiving element according to claim 1,
wherein the substrate contains a semi-insulating semiconductor.

14. The semiconductor light-receiving element according to claim 1,
wherein the substrate contains an insulating substance or a semi-insulating semiconductor, and
the semiconductor lamination portion is bonded to the substrate.
